(19) United States
(12) Patent Application Publication
(10) Pub. No.: US 2001/0050563 A1
(43) Pub. Date: Dec. 13, 2001

(54) STRUCTURE OF A MEMORY CELL

(76) Inventor: CHIH-RONG CHEN, TAITUNG CITY (TW)

Correspondence Address: J.C. PATENTS, INC., 4 Venture, Suite 250, IRVINE, CA, 92618, US

(21) Appl. No.: 09/300,897

(22) Filed: Apr. 28, 1999

(51) Int. Cl. G01R 27/08

(52) U.S. Cl. 324/713

(57) ABSTRACT

A method for measuring contact resistance of a test key pattern is provided. The test key pattern includes several connecting conductive structures and several contacts. The method includes applying a first bias V^{D1} between a first measuring leg and a second measuring leg so as to produce a first current I^{D1}, in which the connecting conductive structures and the contacts are chained together in series between the two legs. The first current is measured. The number of the connecting conductive structures and the number of the contacts between the first and second measuring legs are counted, respectively denoted as B and A, so as to set a first equation of V_{D1}/I_{D1}=A·Rc+B·Rs, where Rs and Rc respectively represent a single resistance of the connecting conductive structures and a single resistance of the contacts. A third measuring leg in between the first and second measuring legs. Performing similar measurement between the first and third measuring legs so that a second equation of V_{D2}/I^{D2}=C·Rc +D·Rs is obtained. Using the first and second equations, the Rs and Rs are simultaneously solved. If the Rs include two parts as Rsm1 and Rsm2, a fourth measuring leg like the third measuring leg can be chosen, and performing the similar measuring procedure as above so that a set of three linear equations with three parameters are obtained for solving the three parameters.

### BACKGROUND OF THE INVENTION

1. Field of the Invention

This invention relates to semiconductor fabrication, and more particularly to a method for measuring a resistance test key in semiconductor fabrication.

2. Description of Related Art

As the integrated circuit (IC) is fabricated in high integration and great complexity, the interconnect is accordingly fabricated in multiple layers through a multilevel metallization process. The multilevel metallization process typically includes two technologies, which are contact fabrication and via fabrication.

The contact fabrication typically includes forming a contact opening in a dielectric layer and a contact opening to fill the contact opening. The contact plug is used to connecting the interconnect layer with a semiconductor substrate at desired locations where metal-oxide semiconductor (MOS) transistors are formed. The via fabrication is similar to the contact fabrication but the via plug is used to connect the multiple interconnect layers. Both types of the plugs includes metallic material, in which tungsten (W) plug and high-temperature aluminum (Al) plug are more widely used.

FIGS. 1A and 1B are cross sectional views, respectively illustrating conventional high-temperature Al-contact and W-contact. In FIG. 1A, a contact opening 14 is formed in a dielectric layer 10 and is filled with an aluminum layer 12. The Al layer 12 serves as a lower layer of an interconnect. In FIG. 1B, the contact opening 16 is filled with a W-plug as dotted, which is further electrically coupled to the aluminum layer 12 serving as the lower layer of the interconnect.

FIGS. 2A and 2 B are cross sectional views, respectively illustrating conventional high-temperature Al-via and W-via. In FIG. 2A, a via opening 24 is formed in a dielectric layer 20, which is formed on a metal layer 26. The via opening 24 is filled with an aluminum layer 22 that also servers a part of an interconnect. In FIG. 2B, a via opening 28 is filled with a W-plug as dotted, which is further electrically coupled to the aluminum layer 22 serving as one of the interconnect layers.

FIG. 3 is structure, schematically illustrating a conventional test key pattern of contact. The test key pattern includes a first measuring leg 30 and a second measuring leg 32. Several test keys 34 of contact between the first measuring leg 30 and the second measuring leg 32 are coupled together by a test-key chain 36. Each of the test keys 34 includes two contacts 42, which are coupled through a metal bar 40 in FIG. 4. FIG. 4 is a cross-sectional view, schematically illustrating the structure in FIG. 3 along the line I-I. In FIG. 3 and FIG. 4, several contacts 42 are formed in a dielectric layer 50, which is formed on a substrate 46. Several doped regions, such as N+ or P+ (N+/P+) regions 44 are formed in the substrate 46. The contacts 42 correspond to dots 42 in FIG. 3. Several interconnect metal bars 40 are formed on the dielectric layer 50 so as to chain all the N+/P+ regions 44 together as the test-key chain 36 through the contacts 42. Each of the test key 34 includes one metal bar of the interconnect layer 40, two contacts 42 that are coupled to two adjacent regions of the N+/P+ regions 44. The bias between the first measuring leg 30 and the second measuring leg 32 is V_{D} by, for example, grounding one and applying another one with V_{D}.

A test key patter usually includes several test keys 34. For example, if the number of the test keys 34 is 60, then the number of the N+/P+ regions 44 is 60 and the number of the contacts 42 is 120. If the resistance of a single contact 42 is Rc and a single N+/P+ region is Rs, the total resistance of the test key pattern is 120 Rs+60 Rc.

As the resistance is measured by a test procedure, an equation is obtained as: V_{D}/I_{D}=120 Rc+60Rs, where I_{D} is the current of the test-key chain 36. The resistance R_{c} of a single contact 42 is therefore derived as Rc=(V_{D}/I_{D}−60 Rc)/120, of which the two parameters Rc and Rs can not be simultaneously monitored. Usually, the resistance Rs is determined by another way so that the quantity of Rc is obtained so as to judge a fabrication status for the actual device on substrate 46. In this manner, the Rc quantity is very dependent on the Rs quantity. The Rs quantity is affected by a doping quality in the N+/P+ regions 44 and the material. If the Rs quantity is biased the R_{c} quantity is biased too. Moreover, the resistance of he metal bars 40 also affects the Rc quantity.

For another manner, the resistance of the metal bars 40 is taken into account as denoted by Rsm1 for each, and the N+/P+ regions 44 are also generally replaced by channel metals each with a resistance Rsm 2. So, V_{D}/I_{D}=120Rc+60 Rsm1+60Rsm2, and Rc=(V_{D}/I_{D}−60Rsm1−60Rsm 2)/120. In similar issue, the Rc quantity is still dependent on Rsm1 and Rsm2.

### SUMMARY OF THE INVENTION

It is at least an objective of the present invention to provide a method for measuring contact resistance of a test key pattern so as to simultaneously measure both the Rs and Rc quantities in one measurement. The Rc is not affected by Rs.

In accordance with the foregoing and other objectives of the present invention, a method for measuring contact resistance of a test key pattern is provided. The test key pattern includes several connecting conductive structures and several contacts. The method includes applying a first bias V_{D1} between a first measuring leg and a second measuring leg so as to produce a first current I_{D1}, in which the connecting conductive structures and the contacts are chained together in series between the two legs. The first current is measured. The number of the connecting conductive structures and the number of the contacts between the first and second measuring legs are counted, respectively denoted as B and A, so as to set a first equation of V_{D1}/I_{D1}=A·Rc+B·Rs, where Rs and Rc respectively represent a single resistance of the connecting conductive structures and a single resistance of the contacts.

A third measuring leg is set between the first measuring leg and the second measuring leg, and a second bias VD₂ is applied between the first measuring leg and the third measuring leg. Performing a similar procedure to the previous procedure, a second current I^{D2} is measured, and a second equation, V_{D2}/I_{D2}=C·Rc+D·Rs, thereby is obtained. The number of the connecting conductive structures and the number of the contacts between the first and third measuring legs are respectively denoted as D and C. According to the first equation and the second equation, a solution of Rs and Rc is obtained.

The method of the invention allows the Rs and Rc to be simultaneously measured through setting the first equation and the second equation and easily solve the equations through an usual mathematical formula. The Rc quantity and the Rs quantity are independently measured in each measurement with affection to each other.

In the foregoing, the first bias V_{D1} and the second bias V_{D2} can be set to be equal so as to further ease the measurement. Each of the connecting conductive structures can include a conventional structure with a metal bar and a channel region formed in a substrate, which are respectively coupled to each side of a corresponding one of the contacts so as to form a test-key chain. The contacts includes Al-contact or W-contact.

In accordance with the foregoing and other objectives of the present invention, another method for measuring resistance of a test key pattern is provided. The test key pattern includes several upper metal bars, several lower metal bars, and several conductive plugs such as metal plugs, all of which are chained together as a chain so as to form the resistance test key pattern. Each of the lower metal bars, each with a resistance of Rsm1, is coupled to an adjacent one of the upper metal bars, each with a resistance of Rsm 2, through one of the metal plugs, each with a resistance of Rc. The test key pattern includes a first measuring leg on one end of the chain, a second measuring leg on the other end of the chain, a third measuring leg and a fourth measuring leg, in which the third and the fourth measuring legs are in between the first measuring leg and the second measuring leg. The location of the third measuring leg is different to the location of the fourth measuring leg. The method includes applying a first bias V_{D1} between the first measuring leg and the second measuring leg, inducing a first current I_{D1}. The number of metal plug, the number of the upper metal bars, and the lower metal bars between the first measuring leg and the second measuring leg is respectively counted as A, B, and C, which form a first equation V_{D1}/I_{D1}=A·R_{c}+B·Rsm1+C·Rsm2.

Similarly, applying the same procedure but only between the first measuring leg and the third measuring leg. A second equation like the first equation except the numbers D, E, and F is obtained as: V_{D2}/I_{D2}=D·Rc+E·Rsm1+F·Rsm2. A third equation is also independently obtained as V_{D3}/I_{D3}=G·Rc+H·Rsm1+I Rsm2·between the first measuring leg and the fourth measuring leg. The V_{D2} and V_{D3} respectively represents a second bias and a third bias, which respectively induce a second current and a third current.

The first, the second, and the third equations form a set of linear equations with three parameters. Since the three equation are independently measured, the Rc, Rsm1, and the Rsm2 can be solved by a standard mathematical formula.

For an easy measuring condition, the first, second, and third biases can be set to be equal. The metal plug typically includes tungsten, aluminum or other metallic material. The lower metal bars can also be replaced by doped region in the substrate.

### BRIEF DESCRIPTION OF DRAWINGS

The invention can be more fully understood by reading the following detailed description of the preferred embodiment, with reference made to the accompanying drawings as follows:

FIGS. 1A and 1B are cross sectional views, respectively illustrating conventional high-temperature Al-contact and W-contact;

FIGS. 2A and 2B are cross sectional views, respectively illustrating conventional high-temperature Al-via and W-via;

FIG. 3 is structure, schematically illustrating a conventional test key pattern of contact;

FIG. 4 is a cross-sectional view, schematically illustrating the structure in FIG. 3 along the line I-I;

FIG. 5 is a structure, schematically illustrating a test key pattern with three measuring legs, according to a first preferred embodiment of the invention; and FIG. 6 is a structure, schematically illustrating a test key pattern with four measuring legs, according to a second preferred embodiment of the invention.

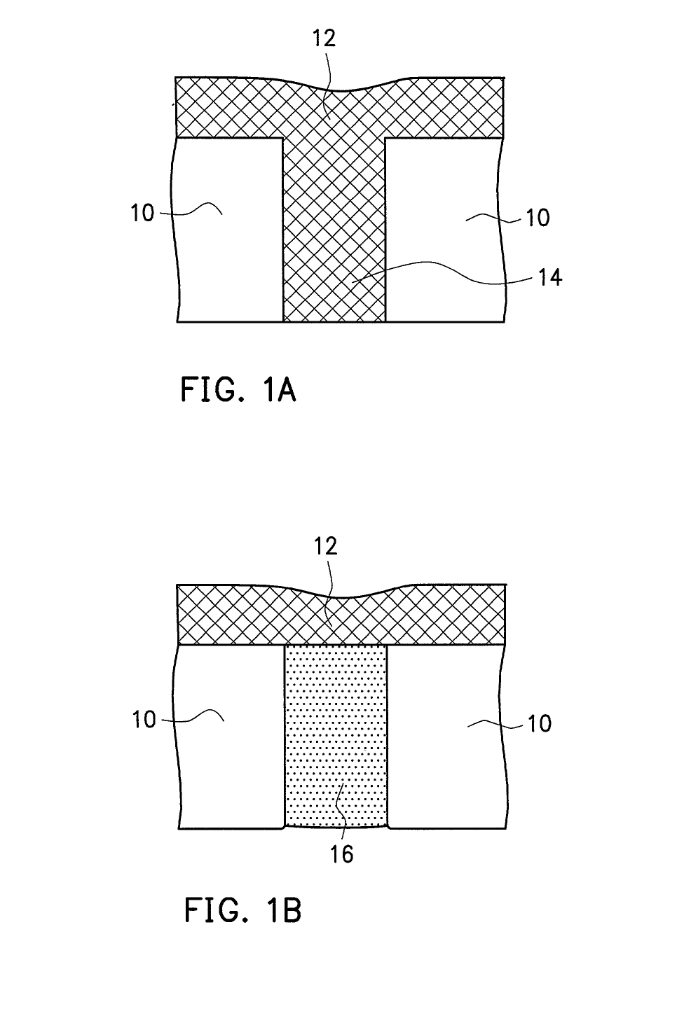

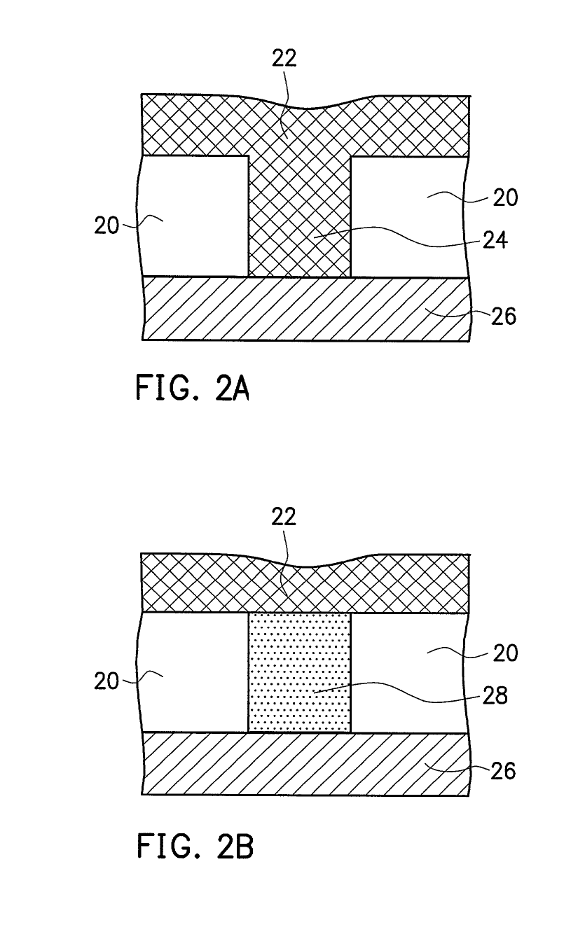

### DETAILED DESCRIPTION OF PREFERRED EMBODIMENTS

The method of the invention makes uses a sufficient set of linear equations to solve all involved resistance parameters in a test key pattern. There is no ambiguity of the measured parameters as it usually is in the conventional method.

### EXAMPLE 1

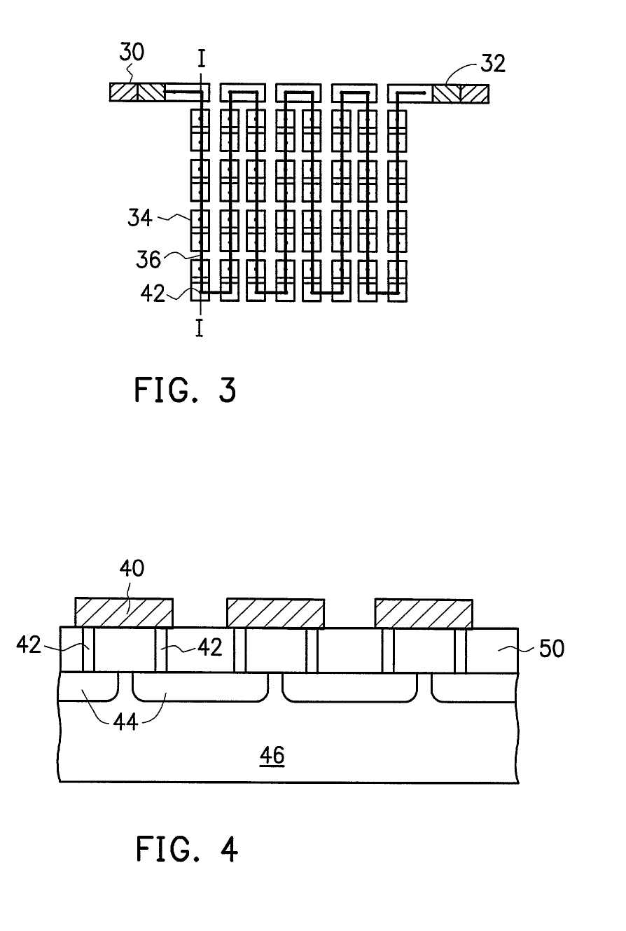

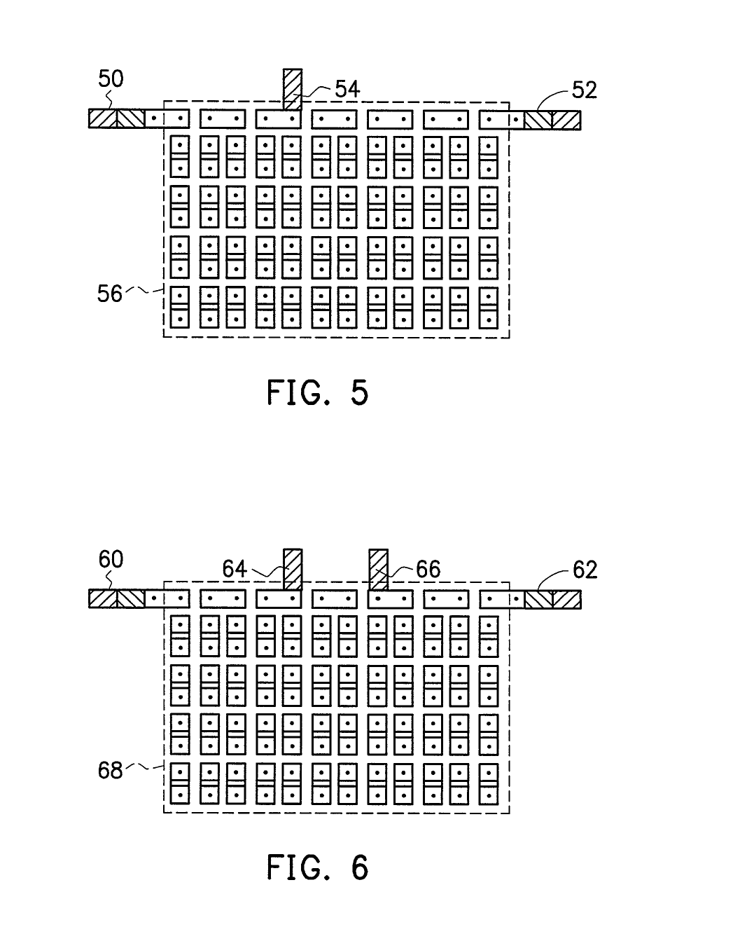

FIG. 5 is a structure, schematically illustrating a test key pattern with three measuring legs, according to a first preferred embodiment of the invention. In FIG. 5, a resistance-test-key pattern 56 include several conventional test keys like the test keys 34 in FIG. 3. The test keys 34 are also chained together as a resistance chain like the previous descriptions in FIG. 3 and FIG. 4.

In the first method of the invention, it includes a first measuring leg 50, a second measuring leg 52, and a third measuring leg. The first measuring leg 50m and the second measuring leg 52 are, for example, located at both ends of the resistance chain. The third measuring leg 54 is further included on one of the test keys between the first and the second measuring legs 50, 52. The number of test keys between the first and the second measuring legs 50, 52 and the number of test keys between the first and the third measuring legs 50, 54 are respectively obtained by, for example, simply counting. Referring to FIG. 4, each of the test keys typically includes a metal bar 40, two conductive plug, such as metal plugs 42, a channel region 44 doped with N+ or P+. The channel region 44 usually incorporates the metal bar 40 to form a connecting structure, which is treated as a single subject with a resistance of Rs. The resistance of one metal plug 42 is denoted as Rc.

After counting, the number of the metal plugs 42 and the number of the connecting structures included in between the first measuring leg 50 and the second measuring leg 52 are respectively obtained and denoted as A and B.

A first measuring equation: V_{D1} /I_{D1}=A·Rc+B·Rs is obtained, where the V_{D1} and I_{D1} respectively are a bias applied between the first and the second measuring legs 50, 52 and the induced current. The first equation can not simultaneously solve the parameters Rc and Rs.

In order to solve the Rc and Rs, a similar measuring procedure is performed to measure the related quantities between the first measuring leg 50 and the third measuring leg 54 by applying a bias V_{D2}. A second equation of V_{D2}/I_{D2}=C·Rc+D·Rs is obtained, where I_{D2} is the induced current, C is the number of the metal plugs 40, and D is the number of connecting structures.

Using a mathematical formula to solve the first equation and the second equation, the quantities Rc and Rs are following:

$$Rc = \vert \begin{matrix}{V}_{D1} / {I}_{D1} & B \\ {V}_{D2} / {I}_{D2} & D\end{matrix} \vert / \vert \begin{matrix}A & B \\ C & D\end{matrix} \vert , \\ Rs = \vert \begin{matrix}A & {V}_{D1} / {I}_{D1} \\ C & {V}_{D2} / {I}_{D2}\end{matrix} \vert / \vert \begin{matrix}A & B \\ C & D\end{matrix} \vert . \qquad ( 1 )$$

For an easy measurement, the V_{D1} can be set to be equal to V_{D2}. By the two independent equations, the Rc and the Rs can be obtained. Since measurements always include measurement errors, a statistic result can also be obtained after several times of measurements.

### EXAMPLE 2

As mentioned above, each of the connecting structure may include two parts, which are coupled together through a conductive plug, such as metal plug. The metal bars 40, shown in FIG. 4, serves as upper metal bars 40, and the channel regions 44, shown in FIG. 4. may be generally replaced by lower metal bars 44. In this manner, three independent equations are needed to solve the three parameters. Each of the plugs has resistance of Rc, each of the upper metal bars has resistance of Rsm1, and each of the lower metal bars has resistance of Rsm2.

With the similar properties of the example 1, a test key pattern with four measuring leg is introduced to measure the resistance in more detail. FIG. 6 is a structure, schematically illustrating a test key pattern with four measuring legs, according to a second preferred embodiment of the invention.

In FIG. 6, a resistance-test-key pattern 68 like the resistance-test-key pattern 56 in FIG. 5. The resistance-test-key pattern 68 includes a first measuring leg 60, a second measuring leg 62, a third measuring leg 64, and a fourth measuring leg 66 on a resistance chain. The first and the second measuring legs 60, 62 are, for example, located on both ends of the resistance chain. The third measuring leg 64 and the fourth measuring leg 66 are in between the first and second measuring legs 60, 62 but at different locations.

As a bias V_{D1} with an induced current I_{D1} is applied between the first and the second measuring legs 60, 62, an equation (2):

V_{D1}/I_{D1}=A·R_{C}+B·Rsm1+C·Rsm2. (2)

Between the first and second measuring legs 60 and 62, the number of the plugs is denoted as A, the number of the upper metal bars 40 is denoted as B, and the number of the lower metal bars 44 is denoted as C.

Another measurement between the first and the third measuring legs 60 and 64, a bias V_{D2} with an induced current I_{D2} is applied, the number of the plugs is denoted as D, the number of the upper metal bars 40 is denoted as E, and the number of the lower metal bars 44 is denoted as F. A equation (3) is obtained:

V_{D2}/I_{D2}=D·Rc+E·Rsm1+F·Rsm2. (3)

Even though the equation (3) is obtained, it is still insufficient to solve the parameters Rc, Rsm1, and Rsm2 without ambiguity.

A further measurement is needed. This measurement is performed between two measuring legs different from the previous combinations, such as between the first measuring leg 60 and the fourth measuring leg 66, or between the third and the second measuring legs 64 and 62. For the example, in FIG. 6, the measurement is performed in between the first and the fourth measuring legs 60, 66. An equation (4) is similarly obtained:

V_{D3}/I_{D3}=G·Rc+H·Rsm1+I·Rsm2. (4)

A bias V_{D3} with an induced current I^{D3} is applied, the number of the plugs is denoted as G, the number of the upper metal bars 40 is denoted as H, and the number of the lower metal bars 44 is denoted as I.

The equations (2)-(4) form a set of linear equation with three parameters Rc, Rsm1, and Rsm2, which can be solved by mathematical formulas (5)-(7):

$$\begin{matrix}Rc = \vert \begin{matrix}{V}_{D1} / {I}_{D1} & B & C \\ {V}_{D2} / {I}_{D2} & E & F \\ {V}_{D3} / {I}_{D3} & H & I\end{matrix} \vert / \vert \begin{matrix}A & B & C \\ D & E & F \\ G & H & I\end{matrix} \vert , & ( 5 ) \\ Rsm1 = \vert \begin{matrix}A & {V}_{D1} / {I}_{D1} & C \\ D & {V}_{D2} / {I}_{D2} & F \\ G & {V}_{D3} / {I}_{D3} & I\end{matrix} \vert / \vert \begin{matrix}A & B & C \\ D & E & F \\ G & H & I\end{matrix} \vert , & ( 6 ) \\ Rsm2 = \vert \begin{matrix}A & B & {V}_{D1} / {I}_{D1} \\ D & E & {V}_{D2} / {I}_{D2} \\ G & H & {V}_{D3} / {I}_{D3}\end{matrix} \vert / \vert \begin{matrix}A & B & C \\ D & E & F \\ G & H & I\end{matrix} \vert . & ( 7 )\end{matrix}$$

For an easy measurement, the biases V_{D1}, V_{D2}, and V_{D3} are, for example, set to be equal. The three parameters Rc, Rsm1, and Rsm 2 can be simultaneously solved for each full measurement of the set of the three equations (2)-(4).

In general if a few more parameters are desired to be measured in detail, a few more independent measured equations are set up by similar procedure with different measuring legs. The metal plug can be any conductive plug, such as the usual tungsten or aluminum.

In conclusion, the invention performs several independent measurement of resistance on the test keys so that a set of linear equations are formed. The parameters are easily solved by mathematical formulas. Resistance of the metal plug resistance and the connection structure is simultaneously measured without ambiguity. When an unusual resistance is detected during semiconductor fabrication procedure, the actual factor can be precisely determined without ambiguity.

The invention has been described using an exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for measuring resistance of a test key pattern, the test key pattern including a plurality of conductive plugs and a plurality of connecting structures so as to form a resistance chain of the conductive plugs, the method comprising:
applying a first bias V_{D1} between a first measuring leg and a second measuring leg, wherein a first current I_{D1} is induced;
counting the number of the conductive plugs and the number of the connecting conductive structures, respectively denoted as A and B, so as to obtain a first equation of V_{D1}/I_{D1}=A·Rc+B·Rs, where Rs and Rc respectively represent resistance of each one of the connecting conductive structures and resistance of each one of the conductive plugs;
choosing a third measuring leg between the first and the second measuring legs, and performing above two steps between the first and the third measuring legs with a second bias V_{D2}, which induces a second current I_{D2} so that a second equation of V_{D2}/I_{D2}=C·Rc+D·Rs is obtained, where C is the number of the conductive plugs and D is the number of the connecting structures between the first and the third measuring legs; and
solving Rc and Rs using the first and the second equations.

2. The method of claim 1, wherein the first bias V_{D1} is equal to the second bias V_{D2}.

3. The method of claim 1, wherein each of the connecting structures comprising a metal bar and a semiconductor doped channel respectively on each side of one of the conductive plugs.

4. The method of claim 3, wherein each the doped channel comprising an N-type doped region or a P-type doped region.

5. The method of claim 1, wherein the conductive plugs comprises tungsten.

6. The method of claim 1, wherein the conductive plugs comprises aluminum.

7. A method for measuring resistance of a test key pattern, which includes a plurality of upper metal bars, a plurality of lower metal bars, and a plurality of conductive plugs, all of which are chained together as a resistance chain in the test key pattern, wherein each of the lower metal bars, with a resistance of Rsm1, is coupled to an adjacent one of the upper metal bars, each with a resistance of Rsm2, through one of the conductive plugs, each with a resistance of Rc, the method comprising:
choosing a first measuring leg on one end of the chain, a second measuring leg on the other end of the chain, a third measuring leg and a fourth measuring leg, in which the third and the fourth measuring legs are in between the first measuring leg and the second measuring leg, and locations of the third and the fourth measuring legs are different;
applying a first bias V_{D1} between the first measuring leg and the second measuring leg, wherein a first current I_{D1} is induced to form a first measured equation of V_{D1}/I_{D1}=A·R_{C}+B·Rsm1+C·Rsm2, where A, B, and C respectively represent the number of conductive plugs, the number of the upper metal bars, and the lower metal bars between the first measuring leg and the second measuring leg;
applying a second bias V_{D2} between the first measuring leg and the second measuring leg, wherein a second current I_{D2} is induced to form a second measured equation of V_{D2}/I_{D2}=D·Rc+E·Rsm1+F·Rsm2, where D, E, and F respectively represent the number of conductive plugs, the number of the upper metal bars, and the lower metal bars between the first measuring leg and the third measuring leg;
applying a third bias V_{D3} between the first measuring leg and the fourth measuring leg, thereby a third current I_{D3}, is induced to form a third measured equation of V_{D3}/I_{D3}=G·Rc+H·Rsm1+I·Rsm2, where G, H, and I respectively represent the number of conductive plugs, the number of the upper metal bars, and the lower metal bars between the first measuring leg and the fourth measuring leg; and
solving the first, the second and the fourth equations to obtain quantities of the Rc, the Rsm1, and the Rsm2.

8. The method of claim 7, wherein the first bias V_{D1}, the second bias V_{D2}, and the third bias V_{D3} are equal to each other.

9. The method of claim 7, wherein the conductive plugs comprise tungsten.

10. The method of claim 7, wherein the conductive plugs comprise aluminum.

11. The method of claim 7, wherein the lower metal bars are replaced with semiconductor doped regions.

12. The method of claim 7, wherein the third measured equation is obtained by applying the third bias V_{D3} between the third measuring leg and the second measuring leg, in which the fourth measuring leg is omitted.

13. A method for measuring resistance of a test key pattern, which includes a plurality of upper metal bars, a plurality of lower metal bars, and a plurality of conductive plugs, all of which are chained together as a resistance chain in the test key pattern, wherein each of the lower metal bars, with a resistance of Rsm1, is coupled to an adjacent one of the upper metal bars, each with a resistance of Rsm2, through one of the conductive plugs each with a resistance of Rc, the method comprising:
choosing a plurality of independent measuring ranges on the resistance chain of the test key pattern;
applying a plurality of biases with respect to the measuring ranges so as to obtain a sufficient set of linear equations with different numbers of the conductive plugs, the upper metal bars, and the lower metal bars;
solving the set of the linear equations to obtain all quantities of parameters of the set of the equations.

14. The method of claim 13, wherein all the applied biases are equal to each other.

15. The method of claim 13, wherein the conductive plugs comprise tungsten.

16. The method of claim 13, wherein the conductive plugs comprise aluminum.

17. The method of claim 13, wherein the lower metal bars are replaced with semiconductor doped regions.
